(19) United States
(12) Patent Application Publication
(10) Pub. No.: US 2024/0258105 A1
(43) Pub. Date: Aug. 1, 2024

(54) COMPOUND SEMICONDUCTOR LAYERED STRUCTURES AND PROCESSES FOR MAKING THE SAME

(71) Applicant: UMICORE, Brussels (BE)

(72) Inventors: Markus LEITGEB, Vienna (AT); Ben DEPUYDT, Olen (BE); Georg PFUSTERSCHMIED, Vienna (AT); Ulrich SCHMID, Vienna (AT)

(21) Appl. No.: 18/562,058

(22) PCT Filed: May 20, 2022
(86) PCT No.: PCT/EP2022/063691

§ 371 Date: Nov. 17, 2023

(30) Foreign Application Priority Data
May 20, 2021 (EP) 21174900.7

(51) Int. Cl. H01L 21/02; H01L 21/04

(52) U.S. Cl. CPC H01L 21/02378; H01L 21/02002; H01L 21/0242; H01L 21/0445

(57) ABSTRACT

The present invention provides a compound semiconductor layered structure comprising: a semiconductor substrate having a bottom surface and a top surface; and a compound semiconductor film on top of said semiconductor substrate, said compound semiconductor film comprising a porous, polycrystalline bottom layer in direct contact with said top surface of said semiconductor substrate, and methods of making the same.

### TECHNICAL FIELD

The present invention relates to novel substrates for preparing compound semiconductor devices and methods for making the same. Specifically, the present invention relates to silicon carbide semiconductors.

### INTRODUCTION

Silicon carbide emerges as a most promising alternative to silicon as semiconductor material, especially for power electronic devices. This is due to its unique material properties, such as wide electronic bandgap and high thermal conductivity. However, in spite of tremendous progress, over the last decades, in both material quality and device manufacturing, widespread adoption is still hampered by the high cost of monocrystalline silicon carbide substrates. The main factors contributing to that high cost are the crystal growth process, the subsequent ingot slicing and the polishing of the substrates.

To avoid energy and material intensive processes, new methods were developed whereby thin layered semiconductor structures are formed and deposited on a support. Hence, much attention has been devoted to developing techniques for forming thin layered semiconductor structures. In this respect, Leitgeb, M. et al. J. Electrochem. Soc. 2017, 164 (12), E337, described novel methods for preparing porous 4H—SiC layers from monocrystalline samples applying photo-electrochemical etching in hydrofluoric acid. It was found that the resulting degree of porosity, the homogeneity in porosity as well as the pore morphology mainly depend on the applied voltage. Importantly, the approach allowed to detach the porous 4H—SiC layers, which comprised several sub-layers of alternating degree of porosity, from the 4H—SiC substrate.

Beside prior art related to the fabrication details of the invention, alternative routes for the detachment of a thin layer from a SiC substrate, and eventual subsequent bonding onto another substrate, are described in literature. In those approaches a line of breakage is created underneath the surface of the mother substrate by utilizing ion implantation. The generated line of breakage allows the mechanical separation of a thin layer from the mother substrate which can subsequently transferred to a polycrystalline substrate. Alternatively, new experimental procedures allow for controlled spalling of a thin semiconductor layer from a substrate by creating a line of breakage underneath the surface of the mother substrate through inducing a mechanical stress via a stressor layer. Such a technique is reported e.g. by Bedell et al. J. Appl. Phys. 122, 2017, 025103; https://doi.org/10.1063/1.4986646.

Present methods still rely on the use of a series of multiple, complex processing steps. As such they have poor materials economy and a nonnegligible environmental impact. The present invention aims to provide new methods for producing monocrystalline semiconductors, those methods allowing for economical use of starting materials, energy-efficiency and flexibility in production. More specifically, the current invention aims at a substantial reduction of the cost, improvement of energy footprint and reduction of waste material.

### SUMMARY OF THE INVENTION

The current invention provides a solution for at least one of the above-mentioned problems by providing a compound semiconductor layered structure, as described in claim 1. The structure according to the first aspect of the invention provides the advantage that a semiconductor film with desired composition and morphology can be provided, i.e. for growing a semiconductor overlayer onto said semiconductor film, preferably for growing a monocrystalline semiconductor overlayer onto said semiconductor film. This allows for a process for preparing a monocrystalline semiconductor overlayer on top of a material- and energy-economic semiconductor substrate. By doing so, dependence on expensive and high carbon footprint bulk substrates is decreased. Waste generation during the production process can be greatly reduced, contributing to an improved carbon dioxide footprint. In a preferred embodiment, said semiconductor substrate is a compound semiconductor substrate.

In a second aspect, the present invention provides a process for preparing a compound semiconductor layered structure according to the first aspect of the invention, whereby a monocrystalline compound semiconductor substrate is porosified using metal-assisted photochemical etching, and exfoliating a compound semiconductor thin film from said semiconductor substrate using a stressor layer. Finally, the isolated compound semiconductor thin film is bonded onto a semiconductor substrate. Such a method is advantageous since it does not affect the bulk properties of the semiconductor substrate material, in contrast to e.g. ion implantation methods.

In a third aspect, the present invention provides an electronic device for power electronics comprising a compound semiconductor layered structure according to the first aspect of the invention.

### DESCRIPTION OF THE FIGURES

By means of further guidance, figures are included to better appreciate the teaching of the present invention. Said figures are intended to assist the description of the invention and are nowhere intended as a limitation of the presently disclosed invention.

The figures and symbols contained therein have the meaning as commonly understood by one of ordinary skill in the art to which this invention belongs.

FIG. 1 schematically shows a cross-section of a compound semiconductor layered structure comprising a semiconductor substrate 1; and a compound semiconductor film 2 on top of said semiconductor substrate 1, said compound semiconductor film 2 comprising a polycrystalline bottom layer 21, a core 22 and a top layer 23.

FIG. 2 schematically shows a cross-section of a compound semiconductor layered structure according to the invention, said compound semiconductor further comprising a semiconductor overlayer 3 on top of said semiconductor film 2.

FIG. 3 shows a SEM micrograph of the cross-section of the Pt-4H-SiC wafer at the interface between the 4H—SiC substrate and the porous surface S-12, S-13.

FIG. 4 shows a SEM micrograph of the cross-section of the Ni-4H-SiC interface after nickel electroplating, whereby Ni has impregnated the porosified surface layer of the Pt-4H-SiC wafer, resulting in enhanced adhesion between the nickel layer and the porous surface layer.

FIG. 5 shows a cross section in perspective of a composite layer comprising nickel and 4H—SiC, as recorded by SEM.

FIG. 6 depicts the surface layer of a thin film 4H—SiC substrate obtained after removal of the nickel stressor layer from the exfoliated thin film. The surface shows residual pores at and/or below the surface, as recorded by TEM.

### DETAILED DESCRIPTION OF THE INVENTION

Unless otherwise defined, all terms used in disclosing the invention, including technical and scientific terms, have the meaning as commonly understood by one of ordinary skill in the art to which this invention belongs. By means of further guidance, term definitions are included to better appreciate the teaching of the present invention.

As used herein, the following terms have the following meanings:

“A”, “an”, and “the” as used herein refers to both singular and plural referents unless the context clearly dictates otherwise. By way of example, “a compartment” refers to one or more than one compartment.

“About” as used herein referring to a measurable value such as a parameter, an amount, a temporal duration, and the like, is meant to encompass variations of +/−20% or less, preferably +/−10% or less, more preferably +/−5% or less, even more preferably +/−1% or less, and still more preferably +/−0.1% or less of and from the specified value, in so far such variations are appropriate to perform in the disclosed invention. However, it is to be understood that the value to which the modifier “about” refers is itself also specifically disclosed.

“Comprise,” “comprising,” and “comprises” and “comprised of” as used herein are synonymous with “include”, “including”, “includes” or “contain”, “containing”, “contains” and are inclusive or open-ended terms that specifies the presence of what follows e.g. component and do not exclude or preclude the presence of additional, non-recited components, features, element, members, steps, known in the art or disclosed therein.

The recitation of numerical ranges by endpoints includes all numbers and fractions subsumed within that range, as well as the recited endpoints. All percentages are to be understood as percentage by weight, abbreviated as “wt. %” or as volume percent, abbreviated as “vol. %”, unless otherwise defined or unless a different meaning is obvious to the person skilled in the art from its use and in the context wherein it is used.

The term “semiconductor” refers to any solid substance that has an electrical conductivity between that of an insulator and that of most metals. An example semiconductor layer is composed of silicon. The semiconductor layer may include a single bulk wafer, or multiple sublayers. Specifically, a semiconductor layer and more preferably a silicon carbide semiconductor layer may include multiple non-continuous porous portions. The multiple non-continuous porous portions may have different densities and may be horizontally distributed or vertically layered.

In the context of the present invention, a compound semiconductor is a semiconductor composed of chemical elements of at least two different species, such as Group III and V elements and Group II and VI elements. These semiconductors typically form in periodic table groups 13-15 (old groups III-V), for example of elements from the Boron group (old group III, boron, aluminium, gallium, indium) and from group 15 (old group V, nitrogen, phosphorus, arsenic, antimony, bismuth). The range of possible formulae is quite broad because these elements can form binary (two elements, e.g. gallium (III) arsenide (GaAs)), ternary (three elements, e.g. indium gallium arsenide (InGaAs)) and quaternary (four elements, e.g. aluminium gallium indium phosphide (AlInGaP)) alloys. GaAs, InP and InGaAIP are used for their application for high-frequency devices and optoelectronic devices. SiC and GaN compound semiconductors are often employed for power semiconductors. Typical compound semiconductors are:
Group II-VI: ZnSe
Group III-V: GaAs, GaN, InP, InGaAIP, InGaN
Group IV-IV: SiC, SiGe

In the context of the present invention, the term “substrate” or “semiconductor substrate” refers the material on which deposited layers may be formed or applied. Exemplary substrates include, without limitation: bulk germanium wafers, bulk silicon wafers, in which a wafer comprises a homogeneous thickness of single-crystal silicon or germanium; composite semiconductor wafers comprising a homogeneous thickness of a mono- or polycrystalline compound semiconductor material; composite wafers, such as a silicon-on-insulator wafer that comprises a layer of silicon that is disposed on a layer of silicon dioxide that is disposed on a bulk silicon handle wafer; or the porous germanium, germanium over oxide and silicon, germanium over silicon, patterned germanium, germanium tin over germanium, and/or the like; or any other material that serves as base layer upon which, or in which, devices are formed. Examples of such other materials that are suitable, as a function of the application, for use as substrate layers and bulk substrates include, without limitation, alumina, silicon carbide, gallium-arsenide, indium-phosphide, silica, silicon dioxide, borosilicate glass, pyrex, and sapphire. A substrate may have a single bulk wafer, or multiple sublayers. Specifically, a substrate (e.g., silicon, germanium, etc.) may include multiple non-continuous porous portions. The multiple non-continuous porous portions may have different densities and may be horizontally distributed or vertically layered. In the context of the present invention, the term “substrate” generally refers to a material having a thickness of at least 1 μm.

In the context of the present invention, the term “film” or “semiconductor film” refers to a material having a substantially-uniform thickness of a material covering a surface. A film can have a porous or a nonporous structure. In the context of the present invention, the term “film” generally refers to a material having a thickness of 0.01 μm to 50 μm.

In the context of the present invention, the term “layer” or “semiconductor layer” refers to a material having a substantially-uniform thickness of a material covering a surface. A layer can be either continuous or discontinuous (i.e., having gaps between regions of the material). For example, a layer can completely or partially cover a surface, or be segmented into discrete regions, which collectively define the layer (i.e., regions formed using selective-area epitaxy). Furthermore, a layer can have a porous or a nonporous structure. In the context of the present invention, the term “layer” generally refers to a material having a thickness of at least 1 μm.

A first layer or a first film described and/or depicted herein as “configured on,” “deposited on,” “on top of,” “on” or “over” a second layer or a second film can be immediately adjacent to the second layer, or one or more intervening layers can be between the first and second layers. In a preferred embodiment of the invention, said first layer or a first film is in direct contact with or bonded with said second layer or said second film. In the context of the present invention, the term “disposed on” means “exists on” an underlying material or layer. This layer may comprise intermediate layers, such as transitional layers, necessary to ensure a suitable surface. For example, if a material is described to be “disposed on a substrate,” this can mean either that the material is in intimate contact with the substrate; or that the material is in contact with one or more transitional layers that reside on the substrate.

In the context of the present invention, the term “surface” refers to a two-dimensional outer face or exterior boundary of a body or part of a body, e.g. a layer; the term “surface area” refers to the size of said surface; and the term “surface layer” refers to a three-dimensional outer layer or exterior boundary of a body or part of a body, e.g. a layer. Hence, in the context of the present invention, the term ‘surface’ is distinguished from the term ‘surface area’ and from the term ‘surface layer.’

Any of the structures depicted and described herein can be part of larger structures with additional layers above and/or below those depicted. For clarity, the figures herein can omit these additional layers, although these additional layers can be part of the structures disclosed. In addition, the structures depicted can be repeated in units, even if this repetition is not depicted in the figures.

The growth and/or deposition described herein may be performed using one or more of chemical vapor deposition (CVD), metalorganic chemical vapor deposition (MOCVD), organometallic vapor phase epitaxy (OMVPE), atomic layer deposition (ALD), molecular beam epitaxy (MBE), halide vapor phase epitaxy (HVPE), pulsed laser deposition (PLD), and/or physical vapor deposition (PVD).

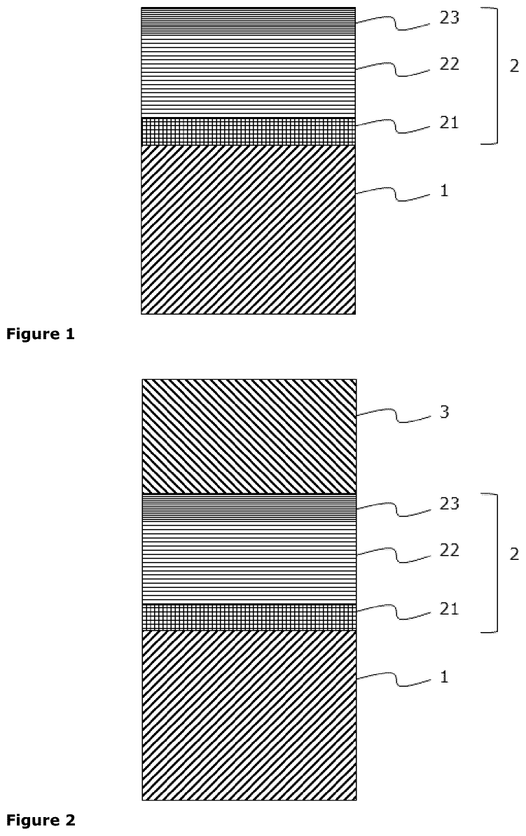

In a first aspect, the present invention provides a compound semiconductor layered structure comprising a semiconductor substrate 1 having a bottom surface and a top surface; and a compound semiconductor film 2 on top of said semiconductor substrate 1, said compound semiconductor film 2 comprising a bottom layer 21, whereby said bottom layer 21 of said compound semiconductor film 2 is in contact with said top surface of said semiconductor substrate 1, and wherein said bottom layer 21 of said compound semiconductor film 2 has a polycrystalline structure. In other words, the bottom layer of said compound semiconductor film is comprised of a polycrystalline material. In a preferred embodiment, said semiconductor substrate 1 comprises a compound semiconductor material. Preferably, said compound semiconductor film 2 is bonded on top of said semiconductor substrate 1. The skilled person will easily distinguish a bonded layer from another layer, e.g., from a SEM analysis of a cross-section of the double-layer. FIG. 1 schematically shows a cross-section of a compound semiconductor layered structure comprising a semiconductor substrate 1; and a compound semiconductor film 2 on top of said semiconductor substrate 1, said compound semiconductor film 2 comprising a polycrystalline bottom layer 21.

The compound semiconductor layered structure according to the invention is advantageous in that it can easily be obtained using a procedure according to the second aspect of the invention. In addition, it is contemplated that surface roughness of said semiconductor substrate does not significantly affect the adhesion of said compound semiconductor film onto said semiconductor substrate. Hence, good adhesion between the semiconductor substrate and the compound semiconductor film can be found, also for semiconductor substrate materials having a comparably higher top surface roughness.

Preferably, the present invention provides a compound semiconductor layered structure according to the first aspect of the invention, wherein said semiconductor substrate and said semiconductor film comprise a material selected from the group consisting of silicon carbide and gallium nitride. In a first embodiment, said semiconductor substrate and said semiconductor film comprise silicon carbide. Preferably, said silicon carbide comprises 4H-silicon carbide (4H—SiC). More preferably, said silicon carbide consists essentially of 4H-silicon carbide (4H—SiC). In a second embodiment, said semiconductor substrate and said semiconductor film comprise gallium nitride.

Preferably, said semiconductor film is in direct contact with said semiconductor substrate. More specifically, said bottom layer of said compound semiconductor film is in direct contact with said top surface of said semiconductor substrate. It may equally be said that said bottom layer of said semiconductor film is directly bonded or fusion bonded onto said top surface of said semiconductor substrate. The structure according to the first aspect of the invention provides the advantage that a semiconductor film with desired composition and morphology can be provided, i.e. for growing a semiconductor overlayer onto said semiconductor film, preferably for growing a monocrystalline semiconductor overlayer onto said semiconductor film. This allows for a process for preparing a monocrystalline semiconductor overlayer on top of a material- and energy-economic semiconductor substrate. By doing so, dependence on expensive and high carbon footprint bulk substrates is decreased. Waste generation during the production process can be greatly reduced, contributing to an improved carbon dioxide footprint. In a preferred embodiment, said semiconductor substrate is a compound semiconductor substrate.

A compound semiconductor film in direct contact with said semiconductor substrate may be obtained by direct bonding or fusion bonding. Direct bonding or fusion bonding is a well-established method of processing known to the skilled person in the field of semiconductor and compound semiconductor processing. It refers to a layer bonding process without any additional intermediate layers. The bonding consists essentially of chemical bonds between two surfaces which are sufficiently clean, flat, smooth and functionalized. The direct bonding or fusion bonding process generally consists of wafer pre-processing, pre-bonding at room temperature and annealing at elevated temperature.

According to the first aspect of the invention, said bottom layer of said compound semiconductor film is porous, as can be determined by SEM of a cross-section of said film. In other words, said bottom layer of said compound semiconductor film comprises pores. This advantageously allows for good adhesion or binding to a substrate, e.g. a polycrystalline SiC substrate. Preferably, the present invention provides a compound semiconductor layered structure according to the first aspect of the invention, wherein said bottom layer of said compound semiconductor film has a porosity of at most 50%, as determined by SEM image analysis, preferably a porosity of 0.1% to 40%. Such procedures for determining porosity from SEM image analysis are well known to the skilled person and are, amongst others, described in Leitgeb, M. et al.

Stacked Layers of Different Porosity in 4H SiC Substrates Applying a Photoelectrochemical Approach. J. Electrochem. Soc. 2017, 164 (12), E337, https://doi.org/10.1149/2.1081712jes. Said bottom layer of said compound semiconductor film preferably has a porosity of 1% to 30%, or of 1% to 15% and even of 1% to 10%, such as 2%, 4%, 6%, 8% or 10%, or any value there in between. Preferably, said bottom layer of said compound semiconductor film has an average pore size of at most 500 nm, as determined by SEM image analysis. Preferably, said bottom layer of said compound semiconductor film has pores having an average pore size of 50 nm to 500 nm, more preferably of 100 nm to 400 nm, and even more preferably of 150 nm to 350 nm. Most preferably said bottom layer of said compound semiconductor film has pores having an average pore size of 160 nm, 170 nm, 180 nm, 190 nm, 200 nm, 210 nm, 220 nm, 230 nm or 240 nm, or any value there in between.

Said bottom layer 21 of said compound semiconductor film 2 further comprises a nonporous surface layer on the bottom surface of said porous bottom layer 21, preferably on the bottom surface of said polycrystalline, porous bottom layer. The nonporous surface layer on the bottom surface of said porous bottom layer may be formed during bonding of an exfoliated semiconductor substrate layer having a porous surface. The nonporous surface layer on the bottom surface of the porous bottom layer is in direct contact with the top surface of said semiconductor substrate 1.

In a preferred embodiment, said compound semiconductor film 2 further comprises a top layer 23, whereby said top layer is nonporous. In other words, said top layer is impervious, dense, compact or closed. This is easily identified by SEM of a cross-section of said film. Preferably, said compound semiconductor film 2 further comprises a core 22, whereby said core is nonporous. In other words, said core is impervious, dense, compact or closed. This is easily identified by SEM of a cross-section of said film.

In a preferred embodiment, the present invention provides a compound semiconductor layered structure according to the first aspect of the invention, wherein said top layer 23 of said compound semiconductor film 2 has a monocrystalline structure. In other words, said top layer is monocrystalline, which allows for growing homoepitaxial layers directly on top of said top layer.

In a preferred embodiment, the present invention provides a compound semiconductor layered structure according to the first aspect of the invention, wherein said polycrystalline bottom layer 21 comprises a plurality of crystallites having an average crystallite size of 10 nm to 200 nm, as determined according to TEM. Preferably, said crystallites have an average crystallite size of 10 nm to 100 nm, and more preferably of 10 nm to 50 nm. Most preferably, said crystallites have an average crystallite size of about 15 nm, 20 nm, 25 nm, 30 nm, 35 nm or 40 nm, or any value there in between.

In a preferred embodiment, the present invention provides a compound semiconductor layered structure according to the first aspect of the invention, wherein said bottom layer 21 has a thickness of 50 nm to 2 μm, as determined according to SEM. In the context of the present invention, said bottom layer 21 is to be understood as a layer consisting of a polycrystalline compound semiconductor material, and being comprised within said compound semiconductor film and on the side of said compound semiconductor film, facing towards said semiconductor substrate, preferably said polycrystalline semiconductor substrate. Preferably, said bottom layer has a thickness of 250 nm to 1500 nm, as determined by SEM, more preferably a thickness of 400 nm to 1200 nm, and most preferably a thickness of about 600 nm, 700 nm, 800 nm, 900 nm, 1000 nm, 1100 nm, 1200 nm, or any value there in between.

In a preferred embodiment, the present invention provides a compound semiconductor layered structure according to the first aspect of the invention, wherein said semiconductor substrate 1 comprises a polycrystalline material. Preferably, said semiconductor substrate comprises the same compound material as the compound semiconductor film on top of said substrate. In an alternative and preferred embodiment, said semiconductor substrate comprises a silicon semiconductor material. This offers the advantage of good fusion between said semiconductor substrate and said semiconductor film, as well as good thermal and mechanical stability of the semiconductor substrate-film assembly.

In a preferred embodiment, the present invention provides a compound semiconductor layered structure according to the first aspect of the invention, wherein said compound semiconductor film 2 has a thickness of at most 50 μm, as determined by SEM image analysis. Preferably, said compound semiconductor film has a thickness of 0.05 μm to 30 μm, and preferably of 0.1 μm to 25 μm, more preferably of 0.5 μm to 16 μm, and even more preferably of 1 μm to 10 μm. Most preferably, said semiconductor film has a thickness of 1 μm to 5 μm, and especially preferred is equal to 1 μm, 2 μm, 3 μm, 4 μm or 5 μm, or any value there in between. Especially preferred, said semiconductor film has a thickness of about 1 μm.

In a preferred embodiment, the present invention provides a compound semiconductor layered structure according to the first aspect of the invention, wherein said compound semiconductor layered structure has a diameter of 1 cm to 50 cm. More preferably, said compound semiconductor layered structure has a diameter of 5 cm to 35 cm. Most preferably, said diameter is about 100 mm or 4 inch, about 150 mm or 6 inch, about 200 mm or 8 inch, or about 300 mm or 12 inch, or any diameter there in between.

In a preferred embodiment, the present invention provides a compound semiconductor layered structure according to the first aspect of the invention, further comprising a semiconductor overlayer 3 having a bottom surface layer and a top surface layer, whereby said bottom surface layer of said semiconductor overlayer 3 is in direct contact with said top layer 23 of said semiconductor film 2. The use of a compound semiconductor film of a predetermined quality on top of a semiconductor substrate of a different quality allows for the use of more readily available materials as substrate materials. In fact, whereas the compound semiconductor film is mainly chosen for the purposes of easily growing a monocrystalline semiconductor layer on top of said film, the substrate may within the concept of the present invention, be selected mainly on the basis of mechanical and cost related characteristics, next to its thermomechanical and electrical compatibility with the compound semiconductor film on top of it. FIG. 2 schematically shows a cross-section of a compound semiconductor layered structure according to the invention, said compound semiconductor further comprising a semiconductor overlayer 3 on top of said semiconductor film 2.

In a preferred embodiment, said semiconductor overlayer is an epitaxially grown semiconductor layer. In the context of the present invention, this means that the semiconductor layer is grown in a type of crystal growth or material deposition process in which new crystalline layers are formed with one or more well-defined orientations with respect to the crystalline semiconductor film. The deposited crystalline semiconductor layer is called an epitaxial layer. The relative orientation(s) of the epitaxial layer to the crystalline film is defined in terms of the orientation of the crystal lattice of each material. For epitaxial growth, the new layer must be crystalline and each crystallographic domain of the overlayer must have a well-defined orientation relative to the film crystal structure.

In a preferred embodiment, the present invention provides a compound semiconductor layered structure according to the first aspect of the invention, wherein said semiconductor substrate 1 comprises one or more materials selected from the group: gallium arsenide (GaAs), gallium nitride (GaN), silicon germanium (SiGe), silicon (Si) and silicon carbide (SIC). Preferably, said semiconductor substrate comprises silicon or silicon carbide, more preferably silicon carbide.

In a preferred embodiment, the present invention provides a compound semiconductor layered structure according to the first aspect of the invention, wherein said semiconductor film 2 comprises one or more materials selected from the group: gallium arsenide (GaAs), gallium nitride (GaN), silicon germanium (SiGe), silicon (Si) and silicon carbide (SIC). Preferably, said semiconductor film comprises silicon or silicon carbide, more preferably silicon carbide.

In a preferred embodiment, the present invention provides a compound semiconductor layered structure according to the first aspect of the invention, wherein said semiconductor overlayer 3 comprises one or more materials selected from the group: gallium arsenide (GaAs), gallium nitride (GaN), silicon germanium (SiGe), silicon (Si) and silicon carbide (SIC). Preferably, said semiconductor layer or overlayer comprises silicon or silicon carbide, more preferably silicon carbide.

In a second aspect, the present invention provides a process for preparing a compound semiconductor layered structure according to the first aspect of the invention, said process comprising the steps of:
i. porosifying a monocrystalline compound semiconductor substrate using metal-assisted photochemical etching, thereby obtaining a monocrystalline compound semiconductor substrate having a porous top surface;
ii. applying a stressor layer onto said porous top surface, thereby forming a stressor layer—substrate wafer;
iii. controlled spalling of said stressor layer from said stressor layer—substrate wafer, thereby exfoliating a compound semiconductor thin film from said semiconductor substrate;
iv. removing said stressor layer from said compound semiconductor thin film, thereby obtaining an isolated compound semiconductor thin film; and
V. bonding said isolated compound semiconductor thin film onto a semiconductor substrate, thereby obtaining a compound semiconductor layered structure.

Preferably, the present invention provides a process according to the second aspect of the invention, wherein said semiconductor substrate and said semiconductor film comprise a material selected from the group consisting of silicon carbide and gallium nitride. In a first embodiment, said semiconductor substrate and said semiconductor film comprise silicon carbide. Preferably, said silicon carbide comprises 4H-silicon carbide (4H—SiC). More preferably, said silicon carbide consists essentially of 4H-silicon carbide (4H—SiC). In a second embodiment, said semiconductor substrate and said semiconductor film comprise gallium nitride. Preferably, the inventive process according to the second aspect of the invention is used for the preparation of a compound semiconductor layered structure according to the first aspect of the invention. Preferably, the process according to the second aspect of the invention is suitable for preparing a compound semiconductor layered structure according to the first aspect of the invention.

Preferably, a semiconductor substrate having a porous surface layer is formed using metal-assisted photochemical etching (MAPCE). In particular, a thin layer of Pt (300 nm) is sputter-deposited at one surface of semiconductor substrate, thereby obtaining a Pt-coated semiconductor wafer. The Pt-coated semiconductor wafer is annealed, e.g. at 1100° C. in Ar atmosphere. Subsequently, a thin porous surface layer having a thickness of about 1 μm is generated at the surface opposite of the Pt layer by immersing the Pt-coated semiconductor wafer in an oxidizing aqueous solution, e.g. containing hydrofluoric acid (approximately 1.3 mol/L) and an oxidizing agent (approximately 0.15 mol/L) (H₂O₂ or Na₂S₂O₈), and irradiating with UV light (wavelength of 254 nm).

Preferably, said semiconductor substrate having a porous surface layer is formed using metal-assisted photochemical etching, whereby a porous surface layer having a porosity of at least 40%, as determined by SEM image analysis, is obtained. Such procedures are well known to the skilled person and are, amongst others, described in Leitgeb, M. et al. Stacked Layers of Different Porosity in 4H SiC Substrates Applying a Photoelectrochemical Approach. J. Electrochem. Soc. 2017, 164 (12), E337, https://doi.org/10.1149/2.1081712jes; Leitgeb, M. et al. Metal Assisted Photochemical Etching of 4H Silicon Carbide. J. Phys. Appl. Phys. 2017, 50 (43), 435301, https://doi.org/10.1088/1361-6463/aa8942. Preferably, said porosity is at least 50%, and more preferably at least 60%. Most preferably, said porosity is between 60% and 90%.

A stressor layer can be applied onto the porous top surface of the monocrystalline compound semiconductor substrate obtained from step i.e. by electroplating, electrodeposition, or sputtering, preferably by electrodeposition or magnetron sputtering. More preferably, said stressor layer can be applied onto said porous top surface of said monocrystalline compound semiconductor substrate by electroplating. Electroplating allows the stressor material to be deposited inside the pores of the porous top surface of the monocrystalline compound semiconductor substrate. Preferably, said stressor layer is comprised of a metal, preferably nickel.

Subsequently, the stressor layer is spalled from said stressor layer—substrate wafer in a controlled manner, thereby exfoliating a compound semiconductor thin film from said semiconductor substrate. In other words, a controlled spalling of a compound semiconductor thin film from said semiconductor substrate is achieved by inducing a stress, preferably a mechanical stress, in said stressor layer in said stressor layer—substrate wafer. This results in the exfoliation of a compound semiconductor thin film from said semiconductor substrate. Spalling is induced by mechanical stress applied onto said stressor layer—substrate. Suitable experimental procedures for controlled spalling are well-documented in literature, e.g. Bedell et al. J. Appl. Phys. 122, 2017, 025103, https://doi.org/10.1063/1.4986646. In the context of the present invention, the term “controlled spalling” of a thin semiconductor layer from a substrate refers to the act of inducing a mechanical stress via said stressor layer on an aggregate of said stressor layer with said substrate, thereby creating a line of breakage underneath the surface of the mother substrate and allowing for the lift-off of a thin semiconductor layer.

In a fourth step, the stressor layer is removed from the compound semiconductor thin film by chemical etching, e.g. by dissolving nickel in a solution containing an oxidizing agent such as H₂O₂ and hydrofluoric acid (HF). Accordingly, an isolated compound semiconductor thin film is obtained. Optionally, the porous layer at the top of the obtained semiconductor layer may further be removed by annealing, preferably at 1000° C. in ambient atmosphere and subsequent removal of the resulting oxide with HF.

In a last step, the obtained isolated compound semiconductor thin film is bonded directly onto a semiconductor substrate, e.g. by heat treatment at a temperature above 1200° C. to form a compound semiconductor layered structure. Preferably, the obtained isolated compound semiconductor thin film is bonded directly onto a polycrystalline semiconductor substrate. Preferably, said isolated compound semiconductor thin film in contact with a semiconductor substrate is subjected to a heat treatment at a temperature above 1400° C., above 1450° C., or even above 1500° C. and below 3000° C., below 2500° C., below 2000° C., below 1800° C., below 1700° C. or even below 1600° C. Preferably, said heat treatment is performed for a period of at least 10 minute, and more preferably at least 15 minutes, at least 20 minutes or at least 30 minutes. Preferably, said heat treatment is performed for a period of at most 8 hours, at most 4 hours, at most 2 hours or even at most 1 hour. Most preferably, said heat treatment is performed for a period of about 30 to 45 minutes. Alternatively, said heat treatment may consist of heating up said isolated compound semiconductor thin film in contact with a semiconductor substrate to a predefined temperature and subsequently cooling down immediately to room temperature.

Preferably, the present invention provides a process according to the second aspect of the invention, whereby said porous semiconductor film in contact with a semiconductor substrate is subjected to a heat treatment at a temperature of 1500° C. to 1600° C., preferably at a temperature above 1550° C., such as 1560° C., 1570° C., 1580° C., 1590° C. or 1600° C. Preferably, said porous semiconductor film in contact with a semiconductor substrate is subjected to a heat treatment under an inert atmosphere, such as argon or helium. Alternatively, said porous semiconductor film in contact with a semiconductor substrate is subjected to a heat treatment under vacuum.

Preferably, the present invention provides a process according to the second aspect of the invention, further comprising the step of forming an epitaxial semiconductor overlayer on top of said semiconductor film.

Preferably, the present invention provides a process according to the second aspect of the invention, wherein said stressor layer consists of nickel, and wherein said compound semiconductor substrate consists of silicon carbide.

In a third aspect, the present invention provides an electronic device for power electronics comprising a compound semiconductor layered structure according to the first aspect of the invention. Power electronic devices according to the third aspect of the invention are suitable for use in applications of converting DC solar power to AC power for domestic use, and regulating functions with regard to battery power in hybrid electric vehicles. The higher bandgap of the compound semiconductor layered structure according to the present invention allows for the electronics that use it to be smaller and operate much more energy-efficiently. Compound semiconductors according to the present invention function at higher temperatures, higher voltages, and higher frequencies than some prior art semiconductors. Furthermore, compound semiconductor layered structure according to the first aspect of the invention can advantageously be used a) as interface layer in SAW devices between piezoelectric layer and silicon substrate, and b) in MEMS, for fabrication of cantilevers or membranes from SiC on Si substrate for harsh environmental applications.

### Example

The following example is intended to further clarify the present invention, and is nowhere intended to limit the scope of the present invention.

### 1. Metal-Assisted Photochemical Etching (MAPCE)

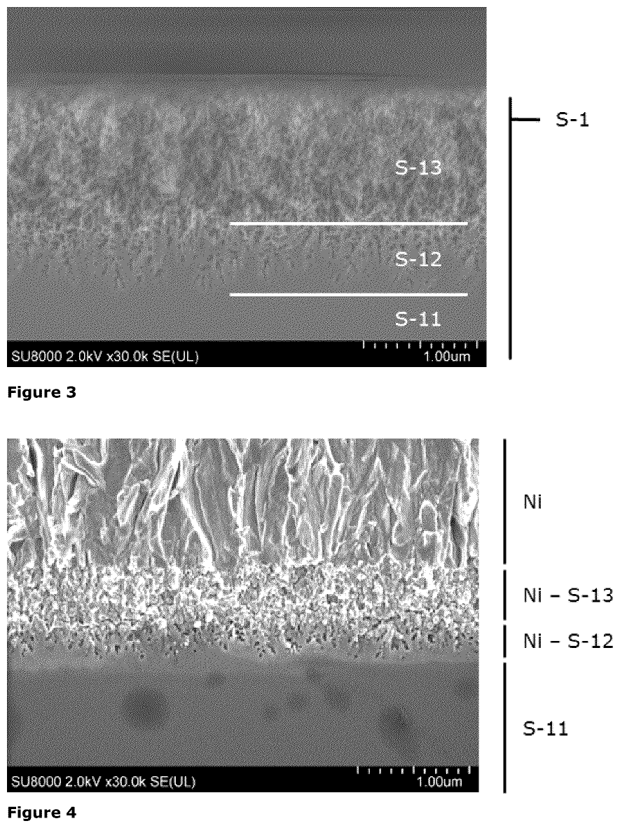

A 4H single crystalline silicon carbide (4H—SiC) substrate having a porous surface layer is formed using metal-assisted photochemical etching (MAPCE). In particular, a thin layer of Pt (300 nm) is sputter-deposited at one surface of a 4H—SiC substrate, thereby obtaining a Pt-4H-SiC wafer. The Pt-4H-SiC wafer is annealed at 1100° C. in Ar atmosphere. Subsequently, a thin porous surface layer having a thickness of about 1 μm is generated at the surface opposite of the Pt layer by immersing the Pt-4H-SiC wafer in an aqueous solution containing hydrofluoric acid (approximately 1.3 mol/L) and an oxidizing agent (approximately 0.15 mol/L) (H₂O₂ or Na₂S₂O₈) and irradiating with UV light (wavelength of 254 nm). Accordingly, a MAPCE-porosified Pt-4H-SiC wafer S-1 is obtained. FIG. 3 shows a SEM micrograph of a detail of the cross-section of the Pt-4H-SiC wafer S-1 at the interface between the core S-11 of the 4H—SiC substrate and the porous surface S-12, S-13 of the 4H—SiC substrate. The porous surface S-12, S-13 of the 4H—SiC substrate comprises a highly porous top surface layer S-13 and a porous top layer of lower porosity S-12. Said porous top layer of higher porosity S-13 is the precursor to a nonporous surface layer of said porous, polycrystalline bottom layer 21 of the final compound semiconductor film 2 of the compound semiconductor layered structure. The nonporous surface layer of said porous, polycrystalline bottom layer 21 is formed from said porous top layer of higher porosity later in the procedure during bonding of the exfoliated semiconductor substrate layer. Said porous top layer of lower porosity S-12 is also referred to as an active layer, and is a precursor to the porous, polycrystalline bottom layer 21 of the final compound semiconductor film 2 of the compound semiconductor layered structure.

### 2. Nickel Electroplating

The porosified Pt-4H-SiC wafer S-1 having a thin porous surface layer S-12, S-13 of about 1 μm is subsequently subjected to nickel electroplating in an electrolyte containing boric acid (35 g/L) and nickel-chloride-hexahydrate (300 g/L). Bare Ni is used as anode; the porosified Pt-4H-SiC wafer S-1 is used as cathode. As such, a circular flow of nickel ions is established and no nickel concentration corrections during plating are necessary. The electrolyte is heated to 75° C. and the MAPCE-porosified Pt-4H-SiC wafer S-1 is immersed into the plating solution by using a wafer holder that protects certain areas of the substrate. Accordingly, a Ni-4H-SiC wafer is obtained. FIG. 4 shows a SEM micrograph of the cross-section of the Ni-4H-SiC interface. The figure shows a Ni layer on top of the 4H—SiC wafer. Ni has penetrated the porous outer layer S-12, S13. The micrograph shows that Ni has impregnated the porosified surface layer of the Pt-4H-SiC wafer, resulting in enhanced adhesion between the nickel layer and the porous surface layer.

### 3. Controlled Spalling of Ni-4H-SiC Wafer

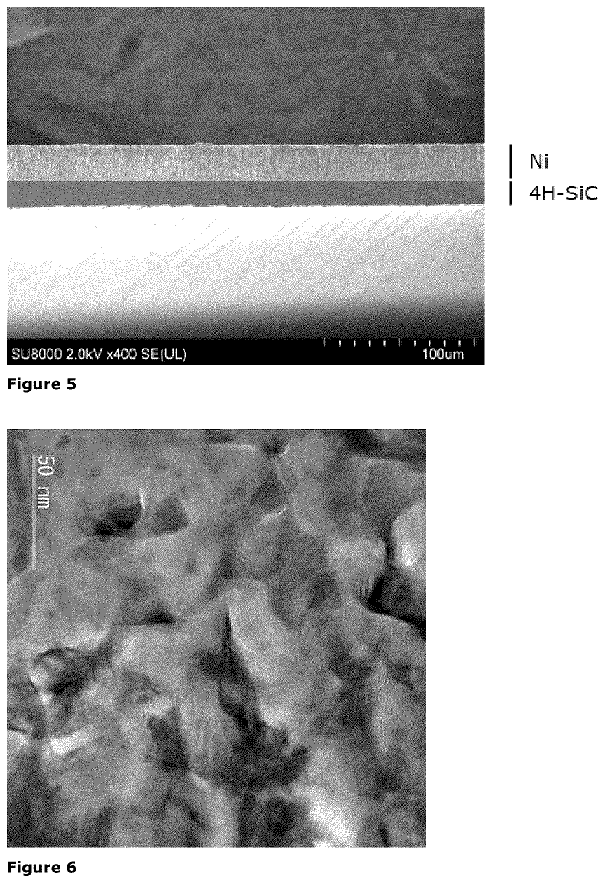

After electroplating, a stress gradient is established at the boundaries of the electroplated nickel layer by applying and subsequently lifting a 25 μm thick polyimide tape as a handling layer. This stress gradient serves as promoter for controlled spalling. The stress gradient induces crack generation. The crack spontaneously propagates across the Ni-4H-SiC wafer. As such, a composite layer comprising nickel and 4H—SiC can be exfoliated from the 4H—SiC wafer, as is shown in FIG. 5. Suitable experimental procedures for controlled spalling are well-documented in literature, e.g. Bedell et al. J. Appl. Phys. 122, 2017, 025103; https://doi.org/10.1063/1.4986646.

### 4. Ni Removal

After controlled spalling, nickel is removed from the exfoliated Ni-4H-SiC thin film by dissolving nickel in a solution containing an oxidizing agent such as H₂O₂ and hydrofluoric acid (HF). Accordingly, a 4H—SiC thin film having a thickness of about 20 μm is obtained. After removal of the porous layer of the 4H—SiC layer, a thin film 4H—SiC substrate is obtained, characterized by a surface layer having residual pores at and/or below the surface. As shown in FIG. 6, TEM investigations showed that the surface comprises pores and a multitude of single crystallites having different orientations.

### 5. Bonding to a Polycrystalline SiC Substrate

The obtained thin film 4H—SiC substrate having a surface layer comprising residual pores at and/or below the surface, is placed on the top surface of a polycrystalline SiC substrate with the surface layer having residual pores faced towards said polycrystalline SiC substrate. The complex is subjected to a heat treatment at a temperature of 1600° C. under an inert He gas atmosphere. It is contemplated that the surface layer comprising said residual pores undergoes a reorganisation during said heat treatment due to minimization of surface energy. This is advantageous because an improved adhesion is obtained, even in case of surface roughness of the polycrystalline SiC substrate.

After the heat treatment, a compound semiconductor layered structure is obtained consisting of a polycrystalline SiC substrate and a semiconductor film on top of said semiconductor substrate. Subsequently, a single crystalline epitaxial layer of 4H—SiC is deposited onto said semiconductor film by chemical vapor deposition. Other methods of deposition can be contemplated as well.

1-16. (canceled)

17. A compound semiconductor layered structure comprising:
i. a silicon carbide semiconductor substrate having a bottom surface and a top surface; and
ii. a silicon carbide semiconductor film bonded on top of said silicon carbide semiconductor substrate, said silicon carbide semiconductor film comprising a bottom layer in direct contact with said top surface of said silicon carbide semiconductor substrate,
characterized in that said bottom layer is porous and polycrystalline.

18. Compound semiconductor layered structure according to claim 17, wherein said silicon carbide compound semiconductor film further comprises a top layer, wherein said top layer is monocrystalline.

19. Compound semiconductor layered structure according to claim 17, wherein said polycrystalline bottom layer comprises a plurality of crystallites having an average crystallite size of 10 nm to 200 nm.

20. Compound semiconductor layered structure according to claim 17, wherein said polycrystalline bottom layer has a porosity of 0.1 to 40%.

21. Compound semiconductor layered structure according to claim 17, wherein said bottom layer has a thickness of 50 nm to 2 μm.

22. Compound semiconductor layered structure according to claim 17, wherein said silicon carbide semiconductor substrate comprises a polycrystalline material.

23. Compound semiconductor layered structure according to claim 17, wherein said silicon carbide semiconductor film has a thickness of at most 50 μm.

24. Compound semiconductor layered structure according to claim 17, wherein said compound semiconductor layered structure has a diameter of 1 cm to 50 cm.

25. Compound semiconductor layered structure according to claim 17, further comprising a silicon carbide semiconductor overlayer having a bottom surface layer and a top surface layer, whereby said bottom surface layer of said silicon carbide semiconductor overlayer is in direct contact with said top layer of said semiconductor film.

26. Process for preparing a compound semiconductor layered structure, comprising the steps of:
i. porosifying a single crystalline, compound semiconductor substrate using metal-assisted photochemical etching, thereby obtaining a single crystalline compound semiconductor substrate (S-1) having a porous top surface (S-12, S-13);
ii. applying a stressor layer onto said porous top surface (S-12, S-13), thereby forming a stressor layer—substrate wafer;
iii. controlled spalling of a compound semiconductor thin film from said semiconductor substrate using said stressor layer in said stressor layer—substrate wafer, thereby exfoliating a compound semiconductor thin film;
iv. removing said stressor layer from said compound semiconductor thin film, thereby obtaining an isolated compound semiconductor thin film; and
v. bonding said isolated compound semiconductor thin film onto a polycrystalline semiconductor substrate, thereby obtaining a compound semiconductor layered structure.

27. Process according to claim 26, subsequently comprising the step of epitaxially growing a semiconductor overlayer (3) on top of the obtained compound semiconductor layered structure.

28. Process according to claim 26, whereby said single crystalline, compound semiconductor substrate comprises silicon carbide.

29. Process according to claim 26, whereby said polycrystalline semiconductor substrate comprises silicon carbide.

30. Process according to claim 26, whereby said stressor layer comprises a metal.

31. Compound semiconductor layered structure obtained by a process according to claim 26.

32. Electronic device for power electronics comprising a compound semiconductor layered structure according to claim 17.
